(19) United States
(12) Patent Application Publication
(10) Pub. No.: US 2010/0308882 A1
(43) Pub. Date: Dec. 9, 2010

(54) FINE DELAY ADJUSTMENT

(75) Inventor: Shiue-shin Liu, Hsin Chu City (TW)

Correspondence Address: KIRTON AND MCCONKIE, 60 EAST SOUTH TEMPLE,, SUITE 1800, SALT LAKE CITY, UT, 84111, US

(73) Assignee: MEDIATEK INC., Hsin-Chu City (TW)

(21) Appl. No.: 12/477,410

(22) Filed: Jun. 3, 2009

(51) Int. Cl. H03H 11/26

(52) U.S. Cl. 327/283

(57) ABSTRACT

A fine delay adjustment device is disclosed. The fine delay adjustment device in accordance with the present invention has at least one delay buffer having an output impedance; a capacitor connected to the delay buffer in series; and a variable resistive unit connected with the capacitor in series. The variable resistive unit has a variable resistance of the same order as the output impedance of the delay buffer. The fine delay adjustment of the present invention is capable of providing sub-ps adjustment steps. In the mean while, an increment due to the fine delay adjustment added to delay time is limited.

### TECHNICAL FIELD OF THE INVENTION

The present invention relates to delay adjustment, more particularly, to a fine delay adjustment device which is capable of providing sub-ps (sub-pico second) order delay adjustment.

### BACKGROUND OF THE INVENTION

Nowadays, in deep-submicron electronic technology, a signal speed (clock rate) is lifted toward GHz order. Under such a high frequency, fine delay adjustment such as sub-pico second (sub-ps) is required.

Taking a 4 GHz sampling time-interleaved ADC (analog-to-digital converter; not shown) as an example, if four sub-ADCs are used, each shares 1 GHz. A first sub-ADC uses a clock CK1, a second sub-ADC uses a clock CK2, a third sub-ADC uses a clock CK3, and a fourth sub-ADC uses a clock CK4. The four clocks are staggered. For example, the pulse of CK1 appears at the first nano second (ns), then the pulse of CK2 appears at the second ns, the pulse of CK3 appears at the third ns and the pulse of CK4 appears at the fourth ns. Ideally, pulse edges of the four clocks should be perfectly aligned. If there is a sampling clock skew of 1 ps occurring among these clocks, it may result in total harmonic distortion (THD) of several dB. Therefore, it is necessary to compensate such a skew by using fine delay adjustment.

FIG. 1 is a schematic circuit diagram showing a delay adjustment device 10 according to prior art. As shown, the delay adjustment device 10 comprises a plurality of delay buffers, two of which (e.g. delay buffers 12, 14) are drawn as representatives. For each delay buffer, such as the delay buffer 12, a plurality of capacitors 17 are connected to an output end Vₐ of the delay buffer 12. The capacitors 17 are connected in parallel with each other. The connection of the capacitors 17 is connected with the delay buffer 12 in series. Each capacitor 17 is connected with a switch 15 in series. By controlling the switches 15, it can be determined to use how many and which ones of the capacitors 17. Then a resultant capacitance can be obtained. The delay time is calculated by multiplying a representative output impedance Rₐ of the delay buffer 12 by the resultant capacitance. However, such a structure has some disadvantages.

When the adjustment is divided into a large number of steps, the wirings become complicated. For example, if there are 32 steps, 32 capacitors 17 and 32 lines are used. Each line introduces an extra parasitic capacitance, which is represented by a capacitor 19, to be loaded on the output end Vₐ of the delay buffer 12. Thus, the intrinsic delay is increased due to the parasitic capacitor 19. Furthermore, the smallest delay which can be attained by the delay adjustment device 10 depends on the smallest capacitance it can be drawn. For example, there are metal/insulator/metal (MiM) capacitors, metal/oxide/metal (MoM) capacitors or MOS capacitors available currently. The smallest capacitor can be made is a capacitor having capacitance of several fF (femto Farad). That is, the smallest adjustment step is the delay obtained by multiplying the capacitance of several fF by the output impedance Rₐ of the delay buffer 12. As known, the output impedance Rₐ of the delay buffer 12 is considerable. Accordingly, it is difficult to achieve fine delay adjustment.

### SUMMARY OF THE INVENTION

The present invention is to provide a fine delay adjustment device. The fine delay adjustment is capable of providing sub-ps adjustment steps. In the mean while, an increment due to the fine delay adjustment added to delay time is very limited in comparison with prior art.

The fine delay adjustment device in accordance with the present invention comprises at least one delay buffer having an output impedance; a capacitor connected to the delay buffer in series; and a variable resistive unit connected with the capacitor in series. The variable resistive unit has a variable resistance of the same order as the output impedance of the delay buffer. The capacitor is selected to have a tiny capacitance. In one embodiment, the variable resistive unit is implemented by a transistor controlled by a DAC (digital-to-analog converter). The DAC provides various control voltages to the transistor, and therefore the transistor offers different resistances correspondingly. In another embodiment, the variable resistive unit is implemented by a plurality of transistors connected in parallel with each other. By controlling ON/OFF states of the respective transistors, different resistances can be provided. By doing so, fine delay adjustment steps are provided for adjusting the delay time of the delay buffer.

The fine delay adjustment device of the present invention can be applied to a voltage controlled oscillator application. The voltage controlled oscillator implementing the technical features of the present invention comprises a delay cell having an output impedance and a pair of differential outputs; a pair of capacitors, each being connected to one of the outputs of the delay cell in series; and a pair of variable resistive units, each being connected with one of the capacitors in series. Each variable resistive unit has a variable resistance of the same order as the output impedance of the delay cell. The variable resistive unit of the voltage controlled oscillator can be implemented as the variable resistive unit described in the embodiments.

### BRIEF DESCRIPTION OF THE DRAWINGS

The present invention will be described in detail in conjunction with the appending drawings, in which:

FIG. 1 is a schematic circuit diagram showing a delay adjustment device according to prior art;

FIG. 2 is a schematic circuit diagram showing a generic design of a fine delay adjustment device according to the present invention;

FIG. 3 is a schematic circuit diagram showing a fine delay adjustment device according to a first embodiment of the present invention;

FIG. 4 is a schematic circuit diagram showing a fine delay adjustment device according to a second embodiment of the present invention;

FIG. 5 is a schematic circuit diagram showing an application example wherein the present invention is applied to a VCO (voltage controlled oscillator);

FIG. 6 is an equivalent circuit diagram showing a noise simulation model of the fine delay device of the present invention;

FIG. 7 is a diagram showing relationship between DAC voltages and delay times of the fine delay adjustment device of FIG. 3; and

FIG. 8 is a schematic circuit diagram showing a fine delay adjustment device according to a third embodiment of the present invention.

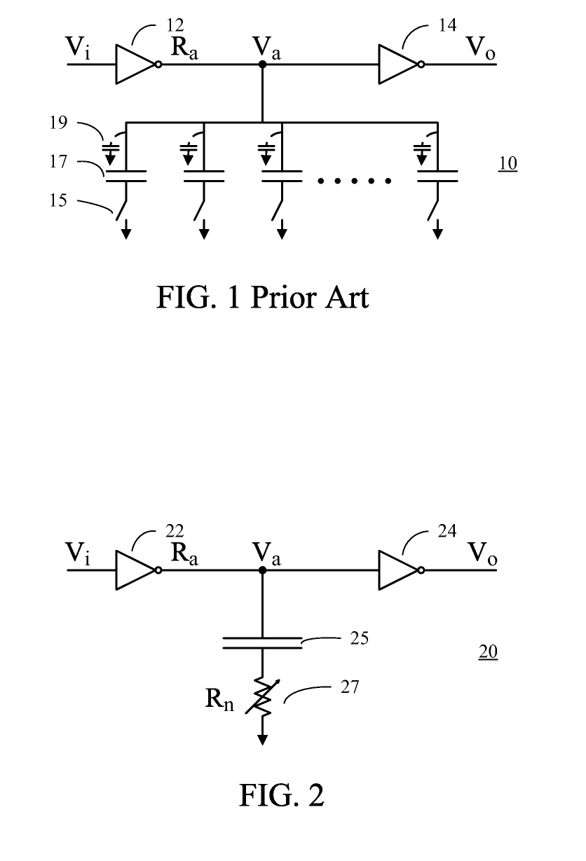

### DETAILED DESCRIPTION OF THE INVENTION

FIG. 2 is a schematic circuit diagram showing a generic fine delay adjustment device 20 according to the present invention. The fine delay adjustment device 20 has a plurality of delay buffers. For the sake of simplicity and clarification, only two delay buffers 22 and 24 are shown. Each delay buffer can be implemented by an inverter. For each delay buffer such as the delay buffer 22, a capacitor 25 and a variable resistive unit 27 are connected to an output end Vₐ thereof in series. That is, the delay buffer 22, the capacitor 25 and the variable resistive unit 27 are connected in series. According to the present invention, to achieve the goal of fine delay adjustment, the variable resistance Rₙ of the variable resistive unit 27 is chosen to be of the same order as the output impedance Rₐ of the delay buffer 22 for effective delay control. Preferably, the variable resistance Rₙ of the variable resistive unit 27 is within a range of 1/10×Rₐ<Rₙ<10×Rₐ. More preferably, the variable resistance Rₙ of the variable resistive unit 27 is within a range of ⅓×Rₐ<Rₙ<3×Rₐ. The capacitor 25 is selected to have a tiny capacitance, such as 1 fF. By varying the variable resistance Rₙ of the variable resistive unit 27, the delay time can be finely adjusted.

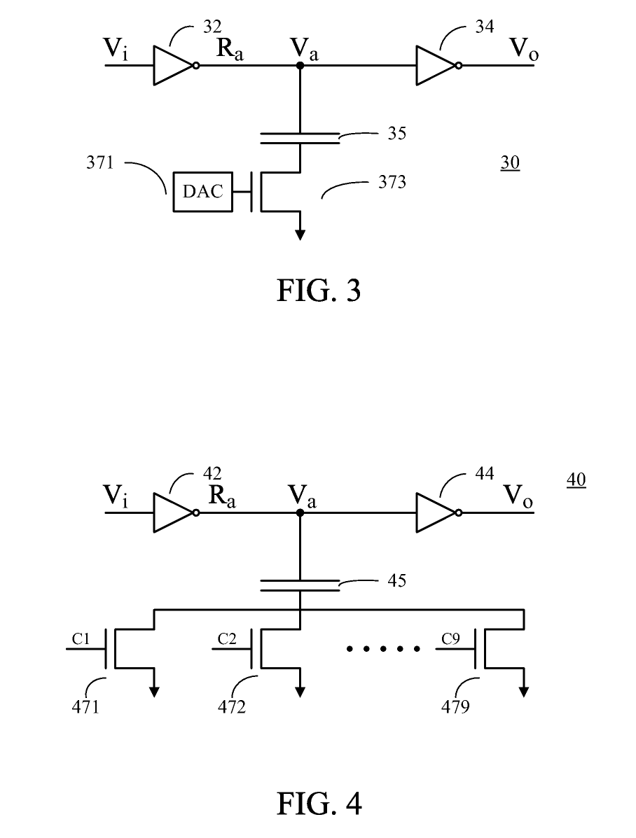

FIG. 3 is a schematic circuit diagram showing a fine delay adjustment device 30 according to a first embodiment of the present invention. The fine delay adjustment device 30 has a plurality of delay buffers. For the sake of simplicity and clarification, only two delay buffers 32 and 34 are shown. Each delay buffer can be implemented by an inverter. For each delay buffer such as the delay buffer 32, one side of a tiny capacitor 35 (e.g. 1 fF or 10 fF) is connected to an output end Vₐ of the delay buffer 32. In the present embodiment, the variable resistive unit is implemented by a transistor 373. In order to obtain a large linear control range, the transistor 373 is preferred to be implemented by a high voltage native NMOS. However, any other suitable type of transistor can also be used. A drain of the transistor 373 is connected to the other side of the capacitor 35 and a source thereof is grounded. A DAC (digital-to-analog converter) 371 is connected to a gate of the transistor 373. The DAC 371 is used to provide different control voltages to the transistor 373 as gate voltages for the transistor 373. As known, a gate-to-source voltage V_{GS} of the transistor 373 is inversely proportional to a resistance thereof. Therefore, by controlling the gate voltage, the provided resistance can be varied as desired. For example, if the DAC 371 outputs 32 discrete and different voltage levels, the transistor 373 will offer 32 different resistances. Accordingly, 32 different delay adjustment steps can be provided by the transistor 373 in cooperation with the capacitor 35. As can be seen, the wiring along the signal path is simple. Although the wiring at the DAC side may be somewhat complicated, the influence will be blocked by the capacitor 35. If the adjustment steps are of a great number (e.g. 1024 steps), such an implementation is especially superior to the prior art. In the latter, a large number (e.g. 1024) of capacitors must be used. It is very easy to adjust the gate voltage by the DAC 371 in a digital manner so as to vary the resistance provided by the transistor 373 of the fine adjustment device 30 according to the present embodiment of the present invention.

If the number of adjustment steps is not so large, the structure of a second embodiment of the present invention can be used. FIG. 4 is a schematic circuit diagram showing a fine delay adjustment device 40 according to the second embodiment of the present invention. The fine delay adjustment device 40 has a plurality of delay buffers. For the sake of simplicity and clarification, only two delay buffers 42 and 44 are shown. Each delay buffer can be implemented by an inverter. For each delay buffer such as the delay buffer 42, one side of a tiny capacitor 45 (e.g. 1 fF) is connected to an output end Vₐ of the delay buffer 42. In the present embodiment, the variable resistive unit is implemented by a plurality of transistors 471, 472, . . . , 479 connected in parallel. For example, all transistors 471, 472, . . . , 479 are connected between ground and the capacitor 45. When being turned on, each of the transistors 471, 472, . . . , 479 provides a fixed resistance. Each transistor 471, 472 or 479 is controlled by a digital signal C1, C2, . . . , or C9 to be turned on or off. The control signals C1, C2, C9 are respectively fed to gates of the transistors 471, 472, . . . , 479. By changing the number of turned-on transistors, the resistance provided between the capacitor 45 and ground is varied. It is noted that the transistors 471, 472, . . . , 479 are selected so that the resultant resistance provided by the turned-on transistors is of the same order as the output impedance Rₐ of the delay buffer 42. By doing so, effective delay control can be achieved. The most significant advantage of the present embodiment is that the transistors 471, 472, . . . , 479 can be switched (i.e. turned on or off) very quickly so as to provide prompt delay adjustment steps of different values. Although the wirings for the transistors 471, 472, . . . , 479 are somewhat complicated and result in parasitic capacitances, the influences will not be observed at the delay buffer 42. As mentioned, the capacitor 45 has a very small capacitance (e.g. 1 nF), the parasitic capacitances due to the wirings of the transistors 471, 472, . . . , 479 are connected with the capacitor 45 is series. Therefore, the effect of the parasitic capacitances is suppressed by the capacitor 45.

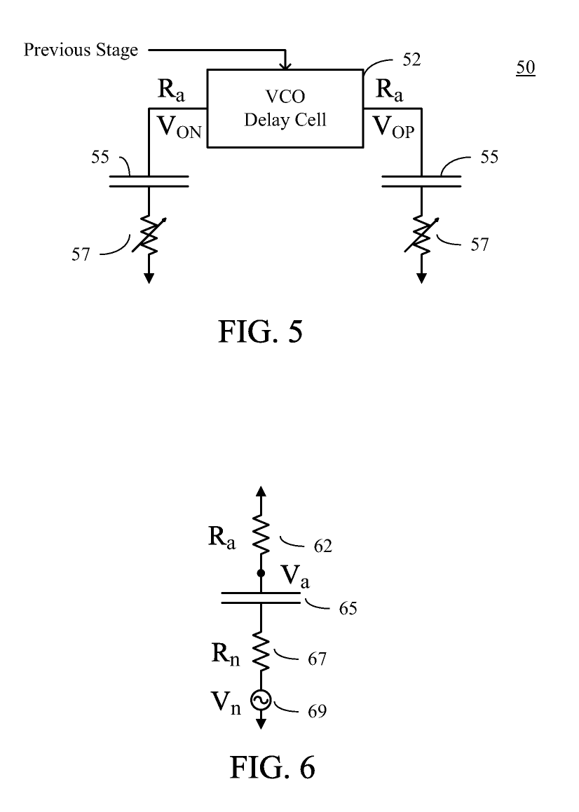

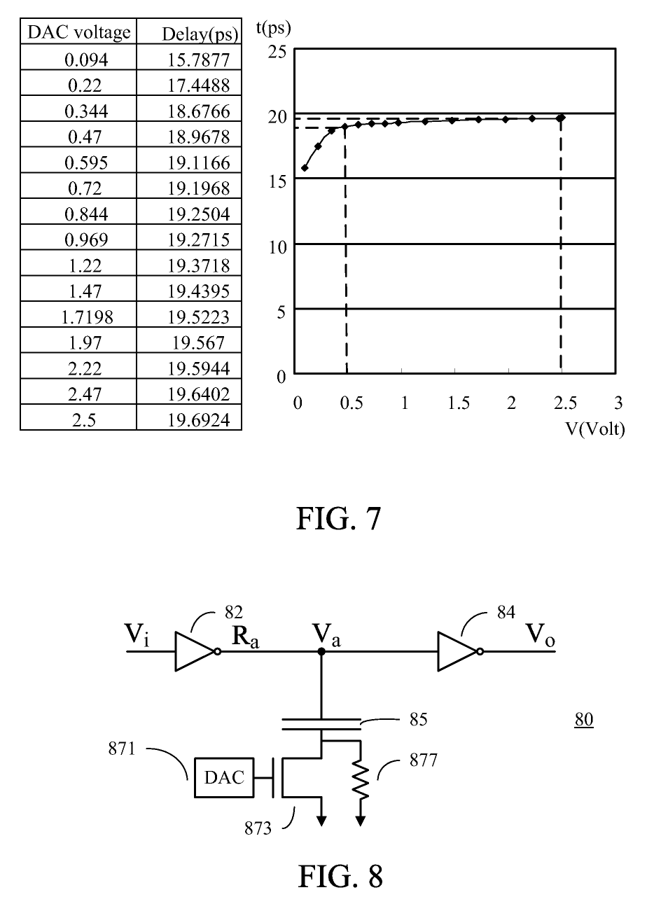

The fine delay adjustment device of the present invention can be applied in various applications. For example, the technique of the present invention can be used in a VCO (voltage control oscillator) to finely adjust VCO frequency so as to minimize quantization error of the digital controlled delay for the VCO. FIG. 5 is a schematic circuit diagram showing an application example wherein the present invention is applied to VCO. In this drawing, a VCO 50 has a VCO delay cell (i.e. delay buffer) 52. The VCO delay cell 52 is connected with another VCO delay cell (not shown) of a previous stage. The VCO delay cell 52 has a pair of differential outputs V_{ON} and V_{OP}, each of which is connected with a capacitor 55 and a variable resistive unit 57 in series. The variable resistive unit 57 can be implemented as variable resistive unit described in the first or second embodiment described above. When the loading connected to the output V_{ON} or V_{OP} is changed, the VCO frequency is changed.

For the VCO application, noise due to the variable resistive unit 57 is needed to be considered since the noise of the variable resistive unit 57 will contribute to the output voltage of the VCO delay cell 52. Significant noise may cause a slicing point (i.e. sampling point) of a succeeding delay cell to be drifted. Through careful analysis, it is found that the noise due to the variable resistive unit 57 is very limited as compared to the thermal noise contributed by the delay cell 52 per se. The details will be further described as follows.

FIG. 6 is an equivalent circuit diagram showing a noise simulation model of the fine delay device of the present invention. Please also refer to FIG. 2. In FIG. 6, a resistor 62 represents the output impedance Rₐ of the delay buffer 22, a capacitor 65 is equivalent to the capacitor 25, a resistor 64 represents the resistance Rₙ of the variable resistive unit 27, and a voltage source 69 simulates the noise Vₐ of the variable resistive unit 27. Then,

$$\begin{matrix}{V}_{n}^{2} = 4 {kTR}_{n} \\ and & ( 1 ) \\ {V}_{a}^{2} = \int [ 4 {kTR}_{n} {\vert \frac{{sCR}_{a}}{1 + sC ( {R}_{a} + {R}_{n} )} \vert}^{2} ] d f & ( 2 )\end{matrix}$$

Assuming Rₙ=Rₐ, then

$$\int [ 4 {kTR}_{a} {\vert \frac{{sCR}_{a}}{1 + 2 {CR}_{a}} \vert}^{2} ] d f < \int {kTR}_{a} d f \qquad ( 3 )$$

in which ∫kTRₐdf is the thermal noise contributed by the delay buffer 22 per se. That is, the worse effect due to the noise Vₙ of the variable resistive unit 27 is less than ¼ of the effect due to the thermal noise contributed by the delay buffer 22 per se. Accordingly, the effect of the noise due to the variable resistive unit 27 is very limited.

A numerical example for 65 nm process will be described herein. Please refer to FIG. 3. Each of the delay buffers 32 and 34 are made by an inverter comprising a PMOS with a width of l m and a length of 70 nm and an NMOS with a width of 0.5 μm and a length of 70 nm. The conductivities of the PMOS and NMOS are 72μ and 50μ, respectively. The capacitance of the capacitor 35 is 10 fF in this example. The transistor 373 is a high voltage native NMOS with a width of 0.5 μm and a length of 1.2 μm. The voltage levels provided by the DAC 371 are in a range from about 0.5V to about 2.5V, as shown in the table of this drawing. The obtained delay times corresponding to these control voltages are also shown in the same table. The delay time measured between the input terminal of the delay buffer 32 and the output terminal of delay buffer 34 (i.e. between Vᵢ and Vₒ in FIG. 3) versus the control voltage provided by the DAC 371 is depicted in the graph of this drawing. As can be seen, a linear adjustment range about 0.7 ps (such as from 18.9678 ps to 19.6924 ps) delay for about 2V voltage range (i.e. about 0.5V to about 2.5V), which is referred to as a linear region, is obtained. When a 4-bit DAC is used, there will be 16 steps. In this case, a very fine delay adjustment step of about 0.04 ps/step (i.e. 0.7/16≈0.04) is achieved. It is noted that the total additional delay increment due to the fine delay adjustment device of the present invention is only 4 ps for DAC control voltage with the range from 0 to 2.5V, which is very small as compared to the prior art.

For the control voltage from the DAC 371 in the range from 0 to 0.5V, the resistance of the NMOS transistor 373 goes from infinite to a finite value. This is the reason why a slight change of the DAC voltage results in a significant delay. To eliminate the nonlinear range of the delay corresponding to the DAC voltage of the range 0 to 0.5V, a possible improvement is proposed as shown in FIG. 8. FIG. 8 is a schematic circuit diagram showing a fine delay adjustment device 80 according to a third embodiment of the present invention. The fine delay adjustment device 80 is similar to that shown in FIG. 3, the only difference is that the fine delay adjustment device 80 further has a tiny resistor 877 connected to a capacitor 85. In the present embodiment, the resistor 877 has one end connected to the capacitor 85 and the other end thereof connected to ground. That is, the resistor 877 is connected in parallel with a transistor 873, which is couple between the capacitor 85 and ground. According, when the transistor 873 is turned off, there is still a small resistance (i.e. the resistance of the resistor 877) connected to the capacitor 85.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

1. A fine delay adjustment device comprising:
a delay buffer comprising an output impedance;
a capacitor connected to the delay buffer in series; and
a variable resistive unit connected with the capacitor in series, the variable resistive unit comprising a variable resistance of the same order as the output impedance of the delay buffer,
wherein the variable resistive unit comprises a transistor coupled between the capacitor and ground, the transistor comprises a gate receiving a control voltage to provide a resistance accordingly,
wherein the variable resistive unit comprises a digital-to-analog converter (DAC) connected to the gate of the transistor for providing a plurality of different control voltages to the transistor so that the transistor provides different resistances accordingly.

2. The fine delay adjustment device of claim 1, wherein the variable resistance of the variable resistive unit is within a range from 1/10 of the output impedance of the delay buffer to 10 times of the output impedance of the delay buffer.

3. The fine delay adjustment device of claim 2, wherein the variable resistance of the variable resistive unit is within a range from ⅓ of the output impedance of the delay buffer to 3 times of the output impedance of the delay buffer.

4. (canceled)

5. (canceled)

6. The fine delay adjustment device of claim 1, wherein the variable resistive unit further comprises a resistor connected in parallel with the transistor.

7. The fine delay adjustment device of claim 1, wherein the variable resistive unit comprises a plurality of transistors connected in parallel with each other and connected to the capacitor in series.

8. The fine delay adjustment device of claim 7, wherein the respective transistors are controlled to be turned on or off, and the resistance of the variable resistive unit depends on the number of turned-on transistors.

9. A voltage controlled oscillator comprising:
a delay cell comprising an output impedance and a pair of differential outputs;
a pair of capacitors, each being connected to one of the outputs of the delay cell in series; and
a pair of variable resistive units, each being connected with one of the capacitors in series, each variable resistive unit comprising a variable resistance of the same order as the output impedance of the delay cell,
wherein each of the variable resistive units comprises a transistor coupled between the capacitor and ground, the transistor comprises a gate receiving a control voltage to provide a resistance accordingly,
wherein and the variable resistive unit comprises a digital-to-analog converter (DAC) connected to the gate of the transistor for providing a plurality of different control voltages to the transistor so that the transistor provides different resistances accordingly.

10. The voltage controlled oscillator of claim 9, wherein the variable resistance of each of the variable resistive units is within a range from 1/10 of the output impedance of the delay buffer to 10 times of the output impedance of the delay buffer.

11. The voltage controlled oscillator of claim 10, wherein variable resistance of each of the variable resistive units is within a range from ⅓ of the output impedance of the delay buffer to 3 times of the output impedance of the delay buffer.

12. (canceled)

13. (canceled)

14. The voltage controlled oscillator of claim 9, wherein the variable resistive unit further comprises a resistor connected in parallel with the transistor.

15. The voltage controlled oscillator of claim 9, wherein each of the variable resistive units comprises a plurality of transistors connected in parallel with each other and connected to the capacitor in series.

16. The voltage controlled oscillator of claim 15 wherein the respective transistors of the variable resistive unit are controlled to be turned on or off, and the resistance of the variable resistive unit depends on the number of turned-on transistors.
